(19) United States
(12) Patent Application Publication
(10) Pub. No.: US 2008/0013962 A1
(43) Pub. Date: Jan. 17, 2008

(54) Pulse-Modulated Signal Demodulation Circuit, and Photoreceiver Circuit and Electric Appliance Provided Therewith

(76) Inventor: Hidetoshi Nishikawa, Kyoto (JP)

Correspondence Address: FISH & RICHARDSON P.C., P.O. BOX 1022, MINNEAPOLIS, MN, 55440-1022, US

(21) Appl. No.: 11/571,639

(22) PCT Filed: Jul. 5, 2005
(86) PCT No.: PCT/JP05/12377

§ 371 Date: Jan. 4, 2007

(30) Foreign Application Priority Data
Jul. 7, 2004 (JP) 2004-200873

(51) Int. Cl. H03K 9/04; H04B 10/06

(52) U.S. Cl. 398/202; 375/239

(57) ABSTRACT

According to the invention, a pulse-modulated signal demodulation circuit has a first integration circuit, a second integration circuit, and a third integration circuit. The first integration circuit generates a first pulse signal containing a pulse having a pulse width corresponding to the number of any consecutive pulses in the pulse-modulated signal. The second integration circuit generates a second pulse signal by removing from the first pulse signal any pulse independent of any other pulse and having a pulse width smaller than or equal to a predetermined pulse width, then producing a pulse corresponding to the pulse width of any pulse in the first pulse signal that is independent of any other pulse and has a pulse width greater than the predetermined pulse width, and then coupling together any pulse in the first pulse signal that is non-independent and thereby producing a pulse corresponding to the pulse width of the non-independent pulse. The third integration circuit generates a third pulse signal by adjusting the pulse width of the second pulse signal according to the pulse width thereof.

### TECHNICAL FIELD

The present invention relates to a pulse-modulated signal demodulation circuit for demodulating a pulse-modulated signal, and to a photoreceiver circuit and an electric appliance incorporating such a pulse-modulated signal demodulation circuit.

### BACKGROUND ART

FIG. 7 shows an example of the configuration of a conventional photoreceiver circuit. FIG. 8 shows a timing chart of the following signals: a code signal transmitted from an infrared-ray remote control transmitter; an optical signal obtained by pulse-modulating that code signal; the signals observed at relevant points in the photoreceiver circuit shown in FIG. 7. The photoreceiver circuit shown in FIG. 7 is for receiving an optical signal transmitted from an infrared-ray remote control transmitter (unillustrated), and includes: a photodiode 101; a current-to-voltage conversion circuit 102; an amplifier 103; a band-pass filter 104; a comparator 105; a constant voltage source 106; an analog integration circuit 107; a comparator 108; a constant voltage source 109; an NPN-type transistor 110; a pull-up resistor 111; and an output terminal 112.

An optical signal LS transmitted from an infrared-ray remote control transmitter (unillustrated) is converted into a current signal by the photodiode 101. The resulting current signal is then converted into a voltage signal by the current-to-voltage conversion circuit 102. The resulting voltage signal is then amplified by the amplifier 103, and is then fed to the band-pass filter 104. Since the optical signal LS transmitted from the infrared-ray remote control transmitter (unillustrated) is a pulse-modulated signal obtained by pulse-modulating a code signal CS, the input signal Vi104 to the band-pass filter 104 also is a pulse-modulated signal as shown in FIG. 8.

The band-pass filter 104 permits, of the signal fed thereto, only the frequency components within a predetermined frequency range to pass therethrough and reach the non-inverting input terminal of the comparator 105. The comparator 105 compares the output signal Vo 104 of the band-pass filter 104 with a constant voltage Vc106 outputted from the constant voltage source 106, and feeds, as the result of the comparison, a comparison signal Vo105 to the analog integration circuit 107.

The analog integration circuit 107 is an analog circuit including a capacitor. When the comparison signal Vo105 is high, the capacitor is charged with a first time constant; when the comparison signal Vo105 is low, the capacitor is discharged with a second time constant smaller than the first time constant. The analog integration circuit 107 outputs, as the output voltage Vo107 thereof, the voltage across the capacitor. The output voltage Vo107 of the analog integration circuit 107 is fed to the non-inverting input terminal of the comparator 108. The comparator 108 compares the output voltage Vo107 of the analog integration circuit 107 with a voltage Vc109 based on a constant voltage outputted from the constant voltage source 109, and feeds, as the result of the comparison, a comparison signal Vo108 to the base of the transistor 110.

The emitter of the transistor 110 is grounded, and the collector of the transistor 110 is connected to the pull-up resistor 111. The node between the collector of the transistor 110 and the pull-up resistor 111 is connected to the output terminal 112. Thus, the signal Vo112 fed out via the output terminal 112 is an inverted version of the comparison signal Vo108.

Configured as described above, the photoreceiver circuit shown in FIG. 7 receives a pulse-modulated signal in the form of an optical signal LS, and outputs a signal that remains low while a pulse is present in the optical signal LS and that remains high while no pulse is present in the optical signal LS.
Patent Document 1: Japanese Patent Application Laid-open No. H9-284231

### DISCLOSURE OF THE INVENTION

### Problems to be Solved by the Invention

Inconveniently, the photoreceiver circuit shown in FIG. 7 has the following disadvantage. When noise causes a missing pulse 114 or an erroneously generated pulse 115 to occur in the comparison signal Vo105 as shown in FIG. 9, a noise component 116 resulting from the missing pulse 114 or a noise component 117 resulting from the erroneously generated pulse 115 remains in the comparison signal Vo108, i.e., the output signal of the pulse-modulated signal demodulation circuit 113 formed by the analog integration circuit 107, the comparator 108, and the constant voltage source 109. Accordingly, a noise component 118 resulting from the missing pulse 114 or a noise component 119 resulting from the erroneously generated pulse 115 remains in the signal Vo112 fed out via the output terminal 112.

Incidentally, Patent Document 1 proposes an optical signal demodulator wherein a digital counter circuit counts the number of pulse signals that occur in synchronism with a clock signal so that, when the number of pulses counted exceeds a predetermined number, a code signal is demodulated based on the pulse signals. Thus, with the optical signal demodulator proposed in Japanese Patent Application Laid-open No. H9-284231 mentioned above, it is possible to eliminate a noise component resulting from erroneously generated pulses of which the number is smaller than or equal to the predetermined number, but not a noise component resulting from missing pulses.

An object of the present invention is to provide a pulse-modulated signal demodulation circuit that yields an output signal with reduced noise components, and to provide a photoreceiver circuit and an electric appliance incorporating such a pulse-modulated signal demodulation circuit.

### Means for Solving the Problem

To achieve the above object, according to one aspect of the present invention, a pulse-modulated signal demodulation circuit is provided with: a first filter circuit; and a second filter circuit. The first filter circuit, on detecting a pulse in the pulse-modulated signal, makes a pulse rise in a first pulse signal and, later on recognizing that no pulse has been present in the pulse-modulated signal for a first predetermined period, makes the pulse in the first pulse signal fall. The second filter circuit, on recognizing that, after the pulse rose in the first pulse signal outputted from the first filter circuit, the pulse has not fallen for a second predetermined period longer than the first predetermined period, makes a pulse rise in a second pulse signal and, later on recognizing that no pulse has been present in the first pulse signal for a third predetermined period longer than the first predetermined period, makes the pulse in the second pulse signal fall.

With this configuration, the first filter circuit generates a first pulse signal by coupling together pulses belonging to every independent group (when a pulse is a predetermined period or more apart from another pulse, these pulses are said to belong to different groups); the second filter circuit generates a second pulse signal by removing from the first pulse signal any pulses whose pulse width is smaller than or equal to a predetermined pulse width and coupling together in the first pulse signal any pulses the intervals between which are smaller than or equal to a predetermined interval. This makes it possible to reduce the noise resulting from erroneously generated pulses or missing pulses in the pulse-modulated signal. Thus, it is possible to reduce the noise components in the output signal of the pulse-modulated signal demodulation circuit.

According to another aspect of the present invention, a pulse-modulated signal demodulation circuit is provided with: a first integration circuit; a second integration circuit; and a third integration circuit. The first integration circuit generates a first pulse signal containing a pulse having a pulse width corresponding to the number of any consecutive pulses in the pulse-modulated signal. The second integration circuit generates a second pulse signal by removing from the first pulse signal any pulse independent of any other pulse and having a pulse width smaller than or equal to a predetermined pulse width, then producing a pulse corresponding to the pulse width of any pulse in the first pulse signal that is independent of any other pulse and has a pulse width greater than the predetermined pulse width, and then coupling together any pulse in the first pulse signal that is non-independent and thereby producing a pulse corresponding to the pulse width of the non-independent pulse. The third integration circuit generates a third pulse signal by adjusting the pulse width of the second pulse signal according to the pulse width thereof.

With this configuration, the first integration circuit generates a first pulse signal containing a pulse having a pulse width corresponding to the number of any consecutive pulses in the pulse-modulated signal; the second integration circuit generates a second pulse signal by removing from the first pulse signal any pulse having a pulse width smaller than a predetermined pulse width and coupling together in the first pulse signal any pulses the intervals between which are smaller than or equal to a predetermined interval; the third integration circuit generates a third pulse signal by adjusting the pulse width of the second pulse signal according to the pulse width thereof. This makes it possible to reduce the noise resulting from erroneously generated pulses or missing pulses in the pulse-modulated signal. Thus, it is possible to reduce the noise components in the output signal of the pulse-modulated signal demodulation circuit.

According to still another aspect of the present invention, a photoreceiver circuit is provided with: a photoreceptive device that receives a pulse-modulated signal in the form of an optical signal; and a pulse-modulated signal demodulation circuit, configured like either of those described above, that is fed with a signal based on a current signal outputted from the photoreceptive device.

With this configuration, it is possible to reduce the noise components in the output signal of the photoreceiver circuit. Thus, it is possible to increase the distance over which the optical signal can reach (i.e., the distance between the optical signal transmitter and the photoreceiver circuit at which the error rate of the output signal of the photoreceiver circuit is equal to the maximum permissible value thereof).

According to a further aspect of the present invention, an electric appliance is provided with: a photoreceiver circuit configured like either of those described above; and a controller that controls the entire electric appliance based on the signal outputted from the photoreceiver circuit.

With this configuration, it is possible to increase the distance over which the optical signal can reach. This helps enhance the usability of the electric appliance.

### Advantages of the Invention

According to the present invention, it is possible to realize a pulse-modulated signal demodulation circuit that yields an output signal with reduced noise components, and to realize a photoreceiver circuit and an electric appliance incorporating such a pulse-modulated signal demodulation circuit.

### BRIEF DESCRIPTION OF DRAWINGS

FIG. 1] is a diagram showing an example of the configuration of a photoreceiver circuit embodying the invention.

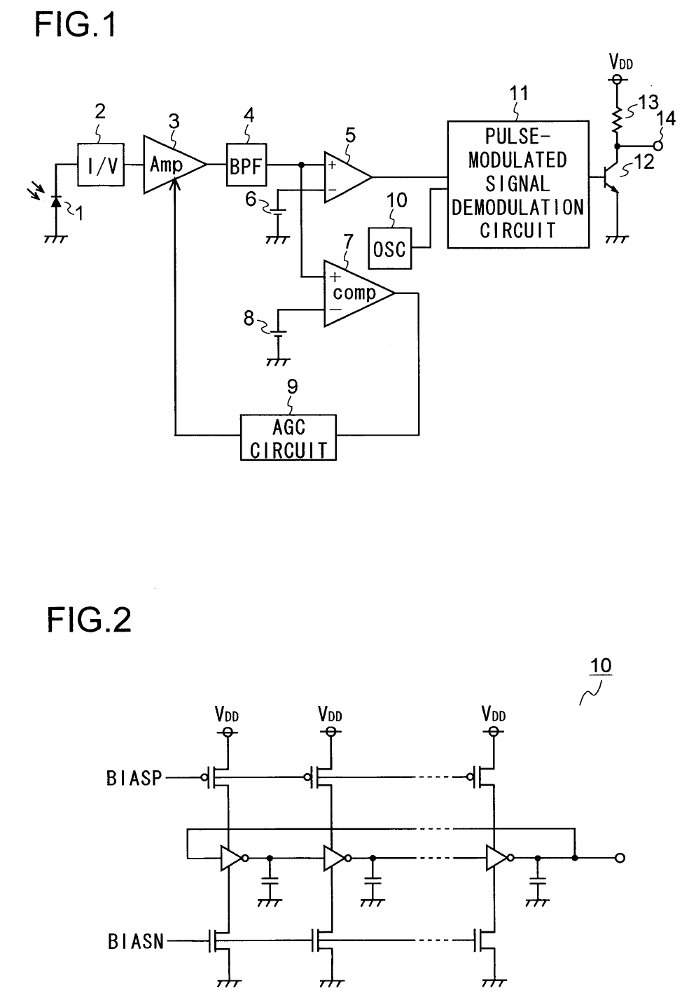

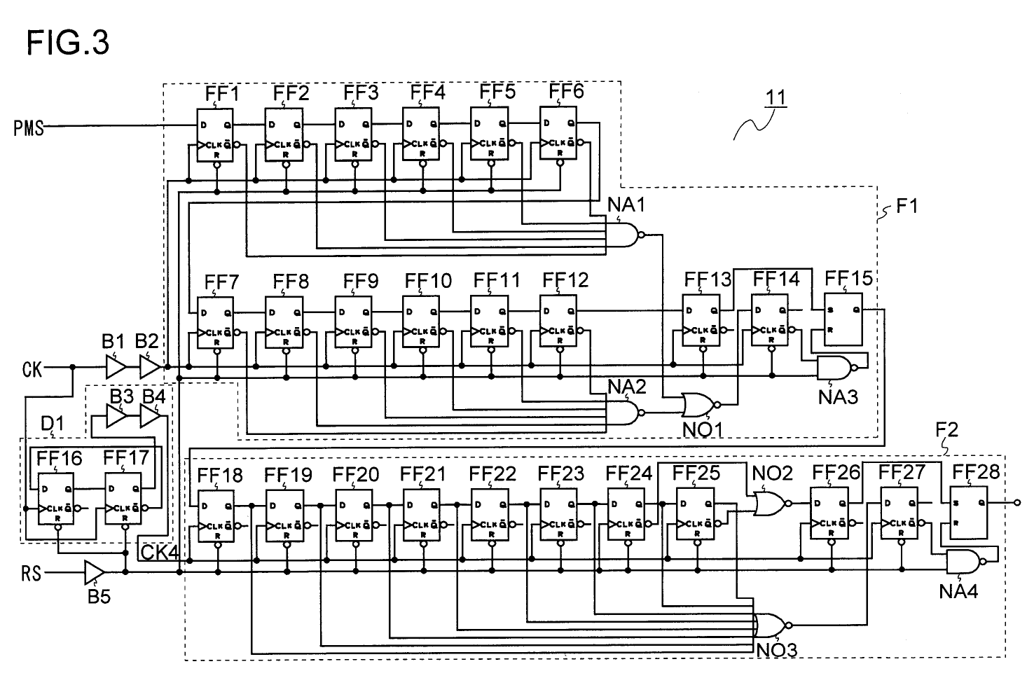

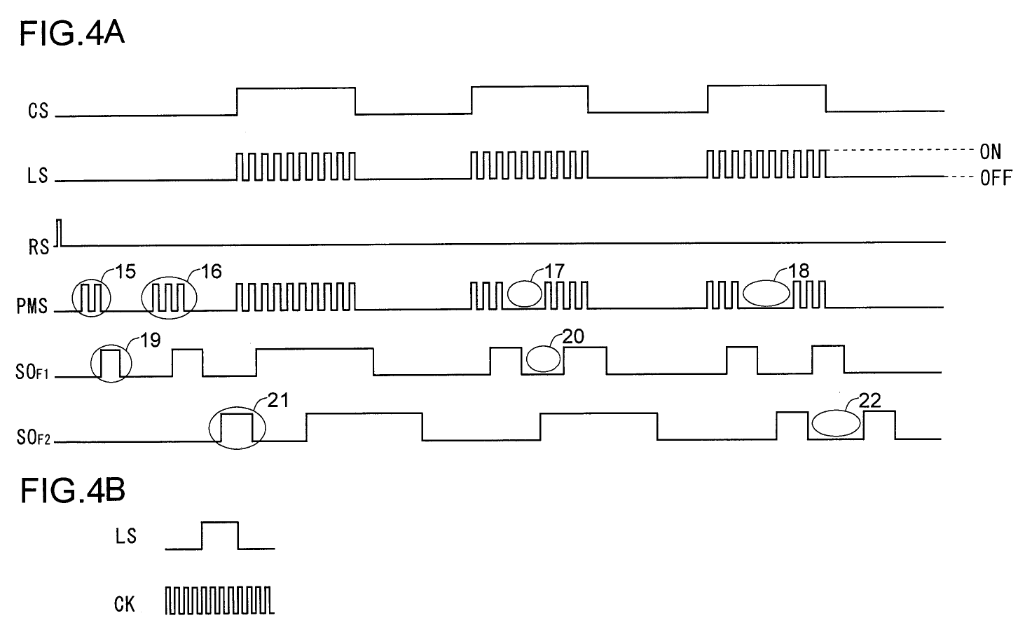

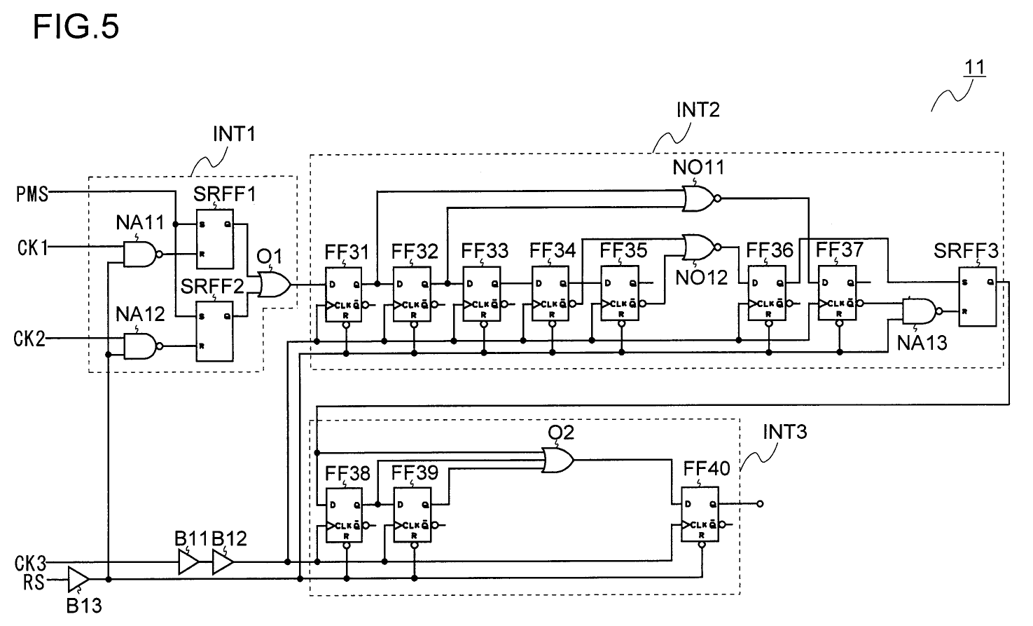

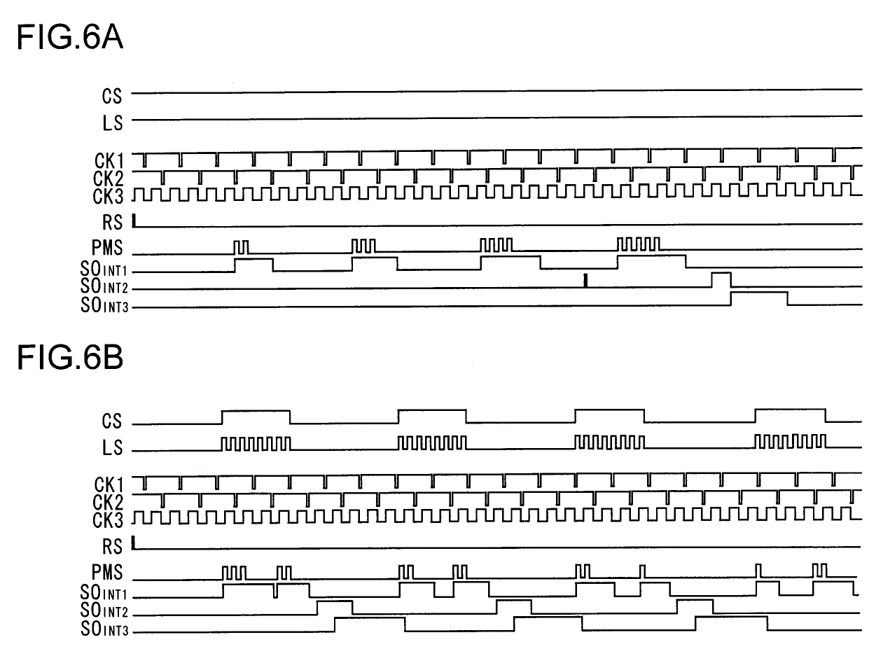

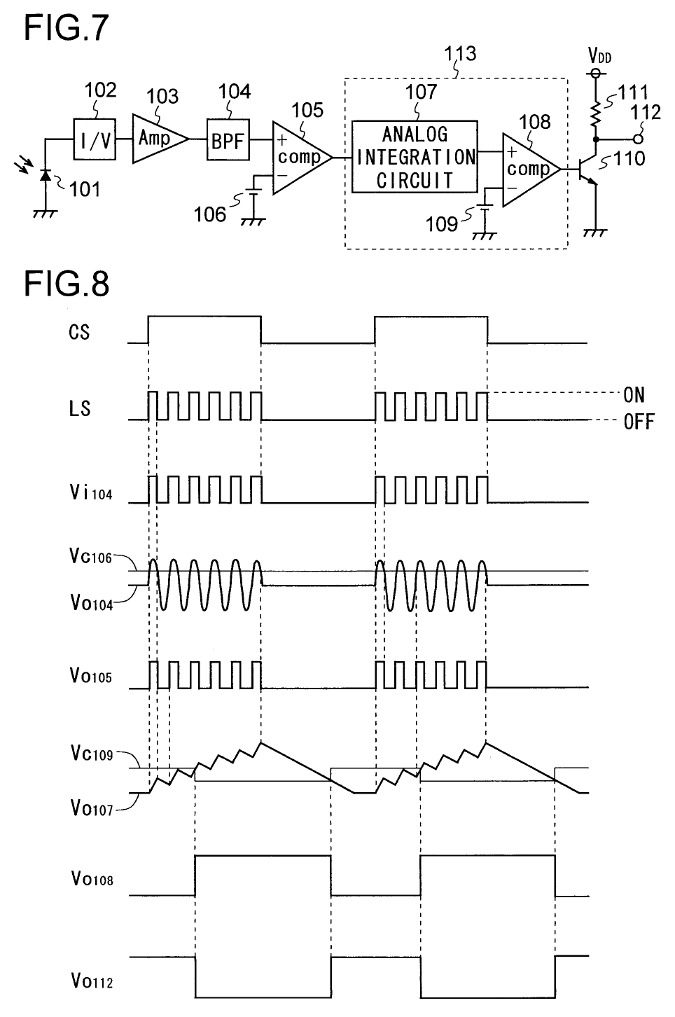

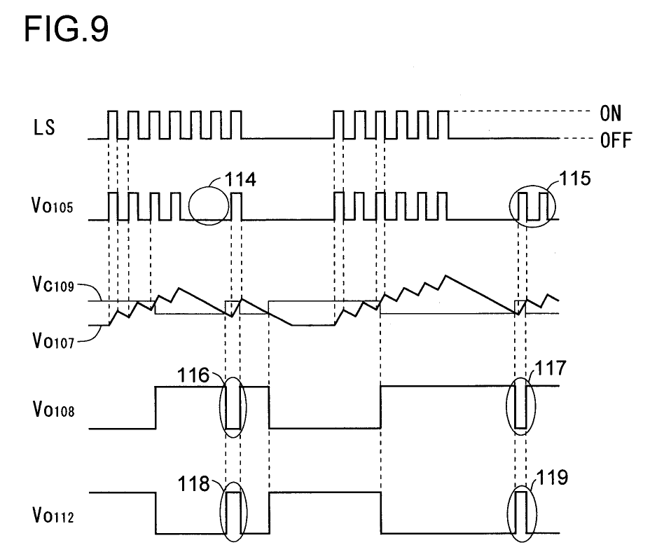

[FIG. 2] is a diagram showing an example of the configuration of the oscillator provided in the photoreceiver circuit shown in FIG. 1.

[FIG. 3] is a diagram showing an example of the configuration of the pulse-modulated signal demodulation circuit provided in the photoreceiver circuit shown in FIG. 1.

[FIG. 4A] and

[FIG. 4B] are timing charts of a code signal, an optical signal, and the signals observed at relevant points in the pulse-modulated signal demodulation circuit shown in FIG. 3.

[FIG. 5] is a diagram showing another example of the configuration of the pulse-modulated signal demodulation circuit provided in the photoreceiver circuit shown in FIG. 1.

[FIG. 6A] and

[FIG. 6B] are timing charts of a code signal, an optical signal, and the signals observed at relevant points in the pulse-modulated signal demodulation circuit shown in FIG. 5.

[FIG. 7] is a diagram showing an example of the configuration of a conventional photoreceiver circuit.

[FIG. 8] is a timing chart of an optical signal transmitted from a remote control transmitter and the signals observed at relevant points in the photoreceiver circuit shown in FIG. 7, when no noise is present.

[FIG. 9] is a timing chart of an optical signal transmitted from a remote control transmitter and the signals observed at relevant points in the photoreceiver circuit shown in FIG. 7, when noise is present.

### LIST OF REFERENCE SYMBOLS

1 photoreceptive device

2 current-to-voltage conversion circuit

3 amplifier

4 band-pass filter

5 operational amplifier

6 constant voltage source

7 comparator

8 constant voltage source

9 AGC circuit

10 oscillator

11 pulse-modulated signal demodulation circuit

12 transistor

13 pull-up resistor

14 output terminal

### BEST MODE FOR CARRYING OUT THE INVENTION

Hereinafter, embodiments of the present invention will be described with reference to the drawings. FIG. 1 shows an example of the configuration of a photoreceiver circuit embodying the invention. The photoreceiver circuit shown in FIG. 1 includes: a photodiode 1; a current-to-voltage conversion circuit 2; a variable-gain amplifier 3; a band-path filter 4; an operational amplifier 5; a constant voltage source 6; a comparator 7; a constant voltage source 8; an AGC circuit 9; an oscillator 10; a pulse-modulated signal demodulation circuit 11; a transistor 12; a pull-up resistor 13; and an output terminal 14.

An optical signal transmitted from an infrared-ray remote control transmitter (unillustrated) is converted into a current signal by the photodiode 1. The resulting current signal is then converted into a voltage signal by the current-to-voltage conversion circuit 2. The resulting voltage signal is then amplified by the amplifier 3, and is then fed to the band-pass filter 4.

The band-pass filter 4 permits, of the signal fed thereto, only the frequency components within a predetermined frequency range to pass therethrough and reach the non-inverting input terminal of the operational amplifier 5 and the non-inverting input terminal of the comparator 7. The operational amplifier 5 compares the output signal of the band-path filter 4 with a constant voltage outputted from the constant voltage source 6, then amplifies the result of the comparison, and then feeds the result to the pulse-modulated signal demodulation circuit 11. The comparator 7 compares the output signal of the band-path filter 4 with a constant voltage outputted from the constant voltage source 8, and feeds the result of the comparison to the AGC circuit 9. According to the output of the comparator 7, the AGC circuit 9 controls the gain of the amplifier 3.

The pulse-modulated signal demodulation circuit 11 receives the output signal of the operational amplifier 5 and a clock signal oscillated by the oscillator 10. Since the optical signal transmitted from the infrared-ray remote control transmitter (unillustrated) to the photodiode 1 is a pulse-modulated signal, the output signal of the operational amplifier 5 also is a pulse-modulated signal. The pulse-modulated signal demodulation circuit 11 demodulates the output signal of the operational amplifier 5, i.e., the pulse-modulated signal, by using the clock signal oscillated by the oscillator 10, and then feeds the resulting demodulated signal to the base of the transistor 12.

The emitter of the transistor 12 is grounded, and the collector of the transistor 12 is connected to the pull-up resistor 13. The node between the collector of the transistor 12 and the pull-up resistor 13 is connected to the output terminal 14. Thus, the signal fed out via the output terminal 14 is an inverted version of the signal outputted from the pulse-modulated signal demodulation circuit 11.

Configured as described above, the photoreceiver circuit shown in FIG. 1 receives a pulse-modulated signal in the form of an optical signal, and outputs a code signal that remains low while a pulse is present in the optical signal LS and that remains high while no pulse is present in the optical signal LS. Moreover, here, as will be described below, the pulse-modulated signal demodulation circuit 11 is so configured as to yield an output signal with reduced noise components. This enables the photoreceiver circuit shown in FIG. 1 to increase the distance over which the optical signal can reach (i.e., the distance between the optical signal transmitter and the photoreceiver circuit at which the error rate of the output signal of the photoreceiver circuit is equal to the maximum permissible value thereof).

Now, the pulse-modulated signal demodulation circuit 11, which is the characteristic portion of the present invention, and the oscillator 10, which oscillates the clock signal used by the pulse-modulated signal demodulation circuit 11, will be described in more detail.

First, the oscillator 10 will be described. FIG. 2 shows an example of the configuration of the oscillator 10. The oscillator shown in FIG. 2 is configured as follows. Several stages of inverter circuits are connected together to form a loop. The output side of each inverter is grounded via a capacitor. Between a terminal via which a drive voltage VDD is fed in and the high-voltage-side supply terminal of each inverter circuit, a P-channel MOS transistor is connected. Between the low-voltage-side supply terminal of each inverter circuit and ground, an N-type MOS transistor is connected. Each P-channel MOS transistor receives, at the gate thereof, a bias voltage BIASP from a voltage source (unillustrated). Each N-channel MOS transistor receives, at the gate thereof, a bias voltage BIASN from a voltage source (unillustrated).

Next, the pulse-modulated signal demodulation circuit 11 will be described. FIG. 3 shows an example of the configuration of the pulse-modulated signal demodulation circuit 11. FIGS. 4A and 4B show timing charts of the following signals: a code signal CS transmitted from an infrared-ray remote control transmitter (unillustrated); an optical signal LS obtained by pulse-modulating that code signal CS; the signals observed at relevant points in the pulse-modulated signal demodulation circuit shown in FIG. 3. Typically, the high-level and low-level periods of the code signal CS transmitted from the infrared-ray remote control transmitter (unillustrated) is each 600 μs, and the pulse period of the optical signal LS is 38 kHz. Thus, typically, the number of consecutive pulses in the optical signal LS is about 20. Here, however, to make the explanations simple, the number of consecutive pulses in the optical signal LS is assumed to be 10.

The pulse-modulated signal demodulation circuit shown in FIG. 3 is composed of flip-flops FF1 to FF28, buffers B1 to B5, NAND gates NA1 to NA4, and NOR gates NO1 to NO3. The flip-flops FF1 to FF15, the NAND gates NA1 to NA3, and the NOR gate NO1 together form a filter circuit F1. The flip-flops FF18 to FF28, the NAND gate NA4, and the NOR gates NO2 and NO3 together form a filter circuit F2. The flip-flops FF16 and FF17 and the buffers B3 and B4 together form a frequency division circuit D1.

The filter circuit F1 has the input end thereof at the data input terminal of the flip-flop FF1, and has the output end thereof at the non-inverting output terminal of the flip-flop FF15. The flip-flops FF1 to FF14 each receive, at the clock input terminal thereof, the clock signal CK oscillated by the oscillator 10. The frequency of the clock signal CK is so determined that one pulse (i.e., one high-level period) in the output signal of the operational amplifier 5, i.e., the pulse-modulated signal PMS fed to the data input terminal of the flip-flop FF1, is equal to four clocks (four periods) of the clock signal CK (see FIG. 4B). Since the pulse period of the optical signal LS transmitted from the infrared ray remote control transmitter (unillustrated) is typically 38 to 40 kHz, in this embodiment, the frequency of the clock signal CK is set at 304 kHz. In the filter circuit F1, when the pulse-modulated signal PMS turns high, the flip-flop FF15 is set, and when the pulse-modulated signal PMS remains low for a period corresponding to 12 clocks of the clock signal CK, the flip-flop FF15 is reset. Thus, the filter circuit F1 functions mainly as an integration circuit, and yields an output signal SOF1 shown in FIG. 4A.

The frequency division circuit D1 receives the clock signal CK, and divides it by a factor of four to feed a clock signal CK4 having a frequency of 76 kHz to the filter circuit F2.

The filter circuit F2 has the input end thereof at the data input terminal of the flip-flop FF18, and has the output end thereof at the non-inverting output terminal of the flip-flop FF28. The output end of the filter circuit F2 serves as the output end of the pulse-modulated signal demodulation circuit 11. The flip-flops FF18 to FF27 each receive, at the clock input terminal thereof, the clock signal CK4. In the filter circuit F2, when the output signal SOF1 of the filter circuit F1 remains high for a period corresponding to two clocks of the clock signal CK4, the flip-flop FF28 is set, and, when the output signal SOF1 of the filter circuit F1 remains low for a period corresponding to eight clocks of the clock signal CK4, the flip-flop FF28 is reset. Thus, the filter circuit F2 removes from the output signal SOF1 of the filter circuit F1 any noise component 19 resulting from a single or two consecutive erroneously generated pulses 15 in the pulse-modulated signal PMS and any noise component 20 resulting from a single, two consecutive, or three consecutive missing pulses 17 in the pulse-modulated signal PMS. As a result, the filter circuit F2 yields an output signal SOF2 shown in FIG. 4A. The output signal SOF2 may still contain a noise component 21 resulting from M (where M is an integer greater than or equal to 3) consecutive erroneously generated pulses 16 in the pulse-modulated signal PMS and a noise component 22 resulting from N (where N is an integer greater than or equal to 4) consecutive missing pulses 18 in the pulse-modulated signal PMS.

Incidentally, by varying the number of stages of flip-flops provided in each of the filter circuits F1 and F2, it is possible to vary the limits beyond which to eliminate noise components.

Moreover, the pulse-modulated signal demodulation circuit shown in FIG. 3 can demodulate the pulse-modulated signal even when the frequency of the clock signal CK is slightly deviated. For example, if the frequency of the clock signal CK deviates from 304 kHz to 228 kHz, the filter circuit F2 removes from the output signal SOF1 of the filter circuit F1 not only any noise component 19 resulting from a single or two consecutive erroneously generated pulses 15 in the pulse-modulated signal PMS and any noise component 20 resulting from a single, two consecutive, or three consecutive missing pulses 17 in the pulse-modulated signal PMS but also a noise component resulting from four consecutive missing pulses 18. In this way, since the pulse-modulated signal demodulation circuit shown in FIG. 3 can demodulate the pulse-modulated signal PMS even when the frequency of the clock signal CK is slightly deviated, the pulse-modulated signal demodulation circuit shown in FIG. 3 and the oscillator 10 can be designed independently of each other.

As will be clear from the foregoing, the pulse-modulated signal demodulation circuit shown in FIG. 3 yields an output signal with reduced noise components. Moreover, since the pulse-modulated signal demodulation circuit shown in FIG. 3 is a digital circuit, the circuit area it occupies can be made smaller than that of the pulse-modulated signal demodulation circuit (analog circuit) provided in the photoreceiver circuit shown in FIG. 7.

Next, another example of the configuration of the pulse-modulated signal demodulation circuit 11 will be described with reference to FIG. 5. FIGS. 6A and 6B show timing charts of the following signals: a code signal CS transmitted from an infrared-ray remote control transmitter (unillustrated); an optical signal LS obtained by pulse-modulating that code signal CS; the signals observed at relevant points in the pulse-modulated signal demodulation circuit shown in FIG. 5. FIG. 6A is a timing chart showing a case in which the code signal CS remains low all the time and in addition noise causes erroneously generated pulses to occur in the pulse-modulated signal PMS. FIG. 6B is a timing chart showing a case in which the code signal CS alternates between high and low and in addition noise causes missing pulses to occur in the pulse-modulated signal PMS. Here, to make the explanations simple, the number of consecutive pulses in the optical signal LS shown in FIG. 6B is assumed to be eight.

It should be noted that, when the pulse-modulated signal demodulation circuit 11 is configured as shown in FIG. 5, the oscillator 10 is configured not as shown in FIG. 2 but as an oscillator that oscillates the three clock signals CK1 to CK3 shown in the time charts of FIGS. 6A and 6B.

The pulse-modulated signal demodulation circuit shown in FIG. 5 is composed of flip-flops FF31 to FF40, S-R flip-flops SRFF1 to SRFF3, buffers B11 to B13, NAND gates NA11 to NA13, NOR gates NO11 and NO12, and OR gates O1 and O2. The flip-flops SRFF1 and SRFF2, the NAND gates NA11 and NA12, and the OR gate O1 together form an integration circuit INT1. The flip-flops FF31 to FF37, the flip-flop SRFF3, the NAND gate NA13, and the NOR gates NO11 and NO12 together form an integration circuit INT2. The flip-flops FF38 to FF40 and the OR gate O2 together form an integration circuit INT3.

The integration circuit INT1 receives the pulse-modulated signal PMS and the clock signals CK1 and CK2, and outputs a signal SOINT1. This signal SOINT1 turns from low to high when the pulse-modulated signal PMS turns from low to high, and turns from high to low when, afterwards while the pulse-modulated signal PMS remains low, the flip-flops SRFF1 and SRFF2 are reset. The output signal SOINT1 of the integration circuit INT1 is a signal containing a pulse having a pulse width corresponding to the number of any consecutive pulses in the pulse-modulated signal PMS (see FIGS. 6A and 6B).

In the integration circuit INT2, when the output signal SOINT1 of the integration circuit INT1 is high at the first and second clocks of the clock signal CK3, the flip-flop SRFF3 is set, and, when the output signal SOINT1 of the integration circuit INT1 is low at the fourth and fifth clocks of the clock signal CK3, the flip-flop SRFF3 is reset. Thus, the signal outputted from the non-inverting output terminal of the flip-flop SRFF3, i.e., the output signal SOINT2 of the integration circuit INT2, is a signal obtained by removing from the output signal SOINT1 of the integration circuit INT1 any pulse independent of (i.e., a predetermined period or more apart from) any other pulse and having a pulse width smaller than or equal to a predetermined pulse width, then producing a pulse corresponding to the pulse width of any pulse in the output signal SOINT1 of the integration circuit INT1 that is independent of any other pulse and has a pulse width greater than the predetermined pulse width, and then coupling together any pulse in the output signal SOINT1 of the integration circuit INT1 that is non-independent and thereby producing a pulse corresponding to a pulse width of the non-independent pulse.

In the integration circuit INT3, while the clock signal CK3 is high, when the output signal SOINT2 of the integration circuit INT2 is high, the flip-flop FF40 is set. When the output signal SOINT2 of the integration circuit INT2 remains low for a period corresponding to three clocks of the clock signal CK3, the flip-flop FF40 is reset. Thus, the output signal SOINT3 of the integration circuit INT3 is a signal obtained by adjusting the pulse width of the output signal SOINT2 of the integration circuit INT2 according to the pulse width thereof (see FIGS. 6A and 6B).

As will be clear from the time charts of FIGS. 6A and 6B, the pulse-modulated signal demodulation circuit shown in FIG. 5 can reduce the noise resulting from erroneously generated pulses or missing pulses in the pulse-modulated signal PMS, and can thus reduce the noise components in the output signal SOINT3. Moreover, the pulse-modulated signal demodulation circuit shown in FIG. 5 requires less flip-flops than the pulse-modulated signal demodulation circuit shown in FIG. 3, thus permitting far greater miniaturization in cases where the flip-flops occupy a large circuit area.

Photoreceiver circuits according to the present invention can be incorporated in various kinds of electric appliances (for example, television and audio appliances) provided with a controller for controlling the entire appliance according to signals outputted from the photoreceiver circuits. Although the embodiments described above deal with cases where a photodiode is used as a photoreceptive device, it is also possible to use any other type of photoreceptive device, for example a phototransistor.

### INDUSTRIAL APPLICABILITY

Pulse-modulated signal demodulation circuit according to the present invention can be applied to photoreceiver circuits and the like. These photoreceiver circuits can be incorporated in various kinds of electric appliances (for example, television and audio appliances) provided with a controller for controlling the entire appliance according to signals outputted from the photoreceiver circuits

1. A pulse-modulated signal demodulation circuit for demodulating a pulse-modulated signal, comprising:
a first filter circuit; and
a second filter circuit,
wherein the first filter circuit,
on detecting a pulse in the modulated-modulated signal, makes a pulse rise in a first pulse signal and,
later on recognizing that no pulse has been present in the modulated-modulated signal for a first predetermined period, makes the pulse in the first pulse signal fall, and
wherein the second filter circuit,
on recognizing that, after the pulse rose in the first pulse signal outputted from the first filter circuit, the pulse has not fallen for a second predetermined period longer than the first predetermined period, makes a pulse rise in a second pulse signal and,
later on recognizing that no pulse has been present in the first pulse signal for a third predetermined period longer than the first predetermined period, makes the pulse in the second pulse signal fall.

2. The pulse-modulated signal demodulation circuit of claim 1, wherein the first and second filter circuits are each a digital circuit.

3. A pulse-modulated signal demodulation circuit for demodulating a pulse-modulated signal, comprising:
a first integration circuit;
a second integration circuit; and
a third integration circuit,
wherein the first integration circuit generates a first pulse signal containing a pulse having a pulse width corresponding to a number of any consecutive pulses in the pulse-modulated signal,
wherein the second integration circuit generates a second pulse signal by
removing from the first pulse signal any pulse independent of any other pulse and having a pulse width smaller than or equal to a predetermined pulse width,
producing a pulse corresponding to a pulse width of any pulse in the first pulse signal that is independent of any other pulse and has a pulse width greater than the predetermined pulse width, and
coupling together any pulse in the first pulse signal that is non-independent and thereby producing a pulse corresponding to a pulse width of the non-independent pulse,
wherein the third integration circuit generates a third pulse signal by adjusting a pulse width of the second pulse signal according to the pulse width thereof.

4. The pulse-modulated signal demodulation circuit of claim 3, wherein the first, second, and third integration circuits are each a digital circuit.

5. A photoreceiver circuit comprising:
a photoreceptive device that receives a pulse-modulated signal in a form of an optical signal; and
a pulse-modulated signal demodulation circuit that is fed with a signal based on a current signal outputted from the photoreceptive device,
wherein the pulse-modulated signal demodulation circuit comprises:
a first filter circuit; and
a second filter circuit,
wherein the first filter circuit,
on detecting a pulse in the modulated-modulated signal, makes a pulse rise in a first pulse signal and,
later on recognizing that no pulse has been present in the modulated-modulated signal for a first predetermined period, makes the pulse in the first pulse signal fall, and
wherein the second filter circuit,
on recognizing that, after the pulse rose in the first pulse signal outputted from the first filter circuit, the pulse has not fallen for a second predetermined period longer than the first predetermined period, makes a pulse rise in a second pulse signal and,
later on recognizing that no pulse has been present in the first pulse signal for a third predetermined period longer than the first predetermined period, makes the pulse in the second pulse signal fall.

6. The photoreceiver circuit of claim 5, wherein the first and second filter circuits are each a digital circuit.

7. A photoreceiver circuit comprising:
a photoreceptive device that receives a pulse-modulated signal in a form of an optical signal; and
a pulse-modulated signal demodulation circuit that is fed with a signal based on a current signal outputted from the photoreceptive device,
wherein the pulse-modulated signal demodulation circuit comprises:
a first integration circuit;
a second integration circuit; and
a third integration circuit,
wherein the first integration circuit generates a first pulse signal containing a pulse having a pulse width corresponding to a number of any consecutive pulses in the pulse-modulated signal,
wherein the second integration circuit generates a second pulse signal by
removing from the first pulse signal any pulse independent of any other pulse and having a pulse width smaller than or equal to a predetermined pulse width,
producing a pulse corresponding to a pulse width of any pulse in the first pulse signal that is independent of any other pulse and has a pulse width greater than the predetermined pulse width, and
coupling together any pulse in the first pulse signal that is non-independent and thereby producing a pulse corresponding to a pulse width of the non-independent pulse,
wherein the third integration circuit generates a third pulse signal by adjusting a pulse width of the second pulse signal according to the pulse width thereof.

8. The photoreceiver circuit of claim 7,
wherein the first, second, and third integration circuits are each a digital circuit.

9. An electric appliance comprising:
a photoreceiver circuit; and
a controller that controls the entire electric appliance based on a signal outputted from the photoreceiver circuit,
wherein the photoreceiver circuit comprises:
a photoreceptive device that receives a pulse-modulated signal in a form of an optical signal; and
a pulse-modulated signal demodulation circuit that is fed with a signal based on a current signal outputted from the photoreceptive device,
wherein the pulse-modulated signal demodulation circuit comprises:
a first filter circuit; and
a second filter circuit,
wherein the first filter circuit,
on detecting a pulse in the modulated-modulated signal, makes a pulse rise in a first pulse signal and,
later on recognizing that no pulse has been present in the modulated-modulated signal for a first predetermined period, makes the pulse in the first pulse signal fall, and
wherein the second filter circuit,
on recognizing that, after the pulse rose in the first pulse signal outputted from the first filter circuit, the pulse has not fallen for a second predetermined period longer than the first predetermined period, makes a pulse rise in a second pulse signal and,
later on recognizing that no pulse has been present in the first pulse signal for a third predetermined period longer than the first predetermined period, makes the pulse in the second pulse signal fall.

10. The electric appliance of claim 9,
wherein the first and second filter circuits are each a digital circuit.

11. An electric appliance comprising:
a photoreceiver circuit; and
a controller that controls the entire electric appliance based on a signal outputted from the photoreceiver circuit,
wherein the photoreceiver circuit comprises:
a photoreceptive device that receives a pulse-modulated signal in a form of an optical signal; and
a pulse-modulated signal demodulation circuit that is fed with a signal based on a current signal outputted from the photoreceptive device,
wherein the pulse-modulated signal demodulation circuit comprises:
a first integration circuit;
a second integration circuit; and
a third integration circuit,
wherein the first integration circuit generates a first pulse signal containing a pulse having a pulse width corresponding to a number of any consecutive pulses in the pulse-modulated signal,
wherein the second integration circuit generates a second pulse signal by
removing from the first pulse signal any pulse independent of any other pulse and having a pulse width smaller than or equal to a predetermined pulse width,
producing a pulse corresponding to a pulse width of any pulse in the first pulse signal that is independent of any other pulse and has a pulse width greater than the predetermined pulse width, and
coupling together any pulse in the first pulse signal that is non-independent and thereby producing a pulse corresponding to a pulse width of the non-independent pulse,
wherein the third integration circuit generates a third pulse signal by adjusting a pulse width of the second pulse signal according to the pulse width thereof.

12. The electric appliance of claim 11,
wherein the first, second, and third integration circuits are each a digital circuit.
